(19) United States
(12) Patent Application Publication
(10) Pub. No.: US 2009/0059404 A1
(43) Pub. Date: Mar. 5, 2009

(54) ELECTRONIC DEVICE HAVING A MIRROR STACK

(75) Inventors: Jian Wang, Goleta, CA (US); Gang Yu, Santa Barbara, CA (US)

Correspondence Address: WOODCOCK WASHBURN LLP, CIRA CENTRE, 12TH FLOOR, 2929 ARCH STREET, PHILADELPHIA, PA, 19104-2891, US

(73) Assignee: E.I. du Pont de Nemours and Company Legal Patent Records Center, Wilmington, DE (US)

(21) Appl. No.: 11/722,134

(22) PCT Filed: Dec. 21, 2005
(86) PCT No.: PCT/US05/46911

§ 371 Date: Oct. 7, 2008

Related U.S. Application Data
(60) Provisional application No. 60/640,783, filed on Dec. 30, 2004.
(60) Provisional application No. 60/694,874, filed on Jun. 28, 2005.

(51) Int. Cl. G02B 5/08

(52) U.S. Cl. 359/850

(57) ABSTRACT

In one embodiment, an electronic device is provided and methods for making the same, as well as devices and sub-assemblies including the same. For example, such an electronic device (FIG. 4) may include a first electronic component (172) designed to be photoactive to a first radiation having a first wavelength, a second electronic component (174) designed to be photoactive to a second radiation having a second wavelength, a first mirror stack (30) adjacent to the first and second electronic components, where the first mirror stack includes a first pair of layers designed to reflect the first radiation and a second mirror stack (40) adjacent to the first and second electronic components, where the second mirror stack includes a second pair of layers designed to reflect the second radiation.

### CROSS REFERENCE

This application claims benefit to U.S. Provisional Application Ser. Nos. 60/640,783, filed Dec. 30, 2004, and 60/694,874, filed Jun. 28, 2005. Furthermore, this application is related to U.S. patent application having Attorney Docket No. DPUC-0142/UC0490 PCT NA, which was filed Dec. 21, 2005. The disclosures of all of the above applications are incorporated by reference herein in their entireties.

### FIELD

This disclosure relates generally to electronic devices and processes, and more specifically to electronic devices having a mirror stack, and materials and methods for fabrication of the same.

### BACKGROUND

Organic electronic devices convert electrical energy into radiation, detect signals through electronic processes, convert radiation into electrical energy, or include one or more organic semiconductor layers. Organic electronic devices can used in displays, sensor arrays, photovoltaic cells, etc. Small molecule organic light-emitting diodes (“SMOLEDs”) and polymer light-emitting diodes (“PLEDs”), both of which are organic light-emitting diodes (“OLEDs”), are types of organic electronic displays. Realizing full colors in such displays, however, has been problematic. For example, it is difficult to fabricate organic materials having color purity that meets CIE standards, because most organic materials have broad emissive or transmissive spectra. Conventional attempts to overcome this shortcoming tend to involve complicated fabrication processes, or produce a device having poor readability or low contrast.

Thus, what is needed are organic electronic devices, and processes for forming same, that address the above shortcomings and drawbacks.

### SUMMARY

In one embodiment, an electronic device is provided, and methods for making the same, as well as devices and sub-assemblies including the same. For example, such an electronic device may include a first electronic component designed to be photoactive to a first radiation having a first wavelength, a second electronic component designed to be photoactive to a second radiation having a second wavelength, a first mirror stack adjacent to the first and second electronic components, where the first mirror stack includes a first pair of layers designed to reflect the first radiation and a second mirror stack adjacent to the first and second electronic components, where the second mirror stack includes a second pair of layers designed to reflect the second radiation.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 is a schematic diagram of an organic electronic device.

The figures are provided by way of example and are not intended to limit the invention. Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

In one embodiment, an electronic device is provided. The electronic device includes a first electronic component designed to be photoactive to a first radiation having a first wavelength, a second electronic component designed to be photoactive to a second radiation having a second wavelength, a first mirror stack adjacent to the first and second electronic components, wherein the first mirror stack includes a first pair of layers designed to reflect the first radiation and a second mirror stack adjacent to the first and second electronic components, wherein the second mirror stack includes a second pair of layers designed to reflect the second radiation.

In one embodiment, the electronic device further includes a third electronic component designed to be photoactive to a third radiation having a third wavelength and a third mirror stack adjacent to the first, second and third electronic components, wherein the third mirror stack includes a third pair of layers designed to reflect the third radiation.

In one embodiment, the first electronic component comprises a first organic light-emitting layer configured to emit blue light, the second electronic component comprises a second organic light-emitting layer configured to emit green light and the third electronic component comprises a third organic light-emitting layer configured to emit red light.

In one embodiment, the electronic device further includes a reflector, and wherein the first and second mirror stacks are located between the first and second electronic components and the reflector.

In one embodiment, the first and second mirror stacks each comprise an even number of layers greater than 2.

In one embodiment, the first mirror stack further comprises a first intervening layer, and the second mirror stack further comprises a second intervening layer.

In one embodiment, a first organic active layer is within the first electronic component; and a second organic active layer is within the second electronic component.

In one embodiment, a process for forming an electronic device is provided. The process includes forming a first electronic component designed to be photoactive to a first radiation having a first wavelength, forming a second electronic component designed to be photoactive to a second radiation having a second wavelength, forming a first mirror stack, wherein the first mirror stack includes a first pair of layers designed to reflect the first radiation and forming a second mirror stack, wherein the second mirror stack includes a second pair of layers designed to reflect the second radiation.

In one embodiment, forming each layer within the first pair of layers to have a first actual thickness that is within 10% of a first calculated thickness, and forming each layer within the second pair of layers to have a second actual thickness that is within 10% of a second calculated thickness.

In one embodiment, the process further includes forming a third electronic component designed to be photoactive to a third radiation having a third wavelength and forming a third mirror stack, wherein the third mirror stack includes a third pair of layers designed to reflect the third radiation.

In one embodiment, each layer within the third pair of layers has a third actual thickness that is within 10% of a third calculated thickness.

In one embodiment, the first electronic component comprises a first organic light-emitting layer configured to emit blue light, the second electronic component comprises a second organic light-emitting layer configured to emit green light and the third electronic component comprises a third organic light-emitting layer configured to emit red light.

In one embodiment, the first and second mirror stacks lie between the first electronic component and a user surface of the electronic device and the first and second mirror stacks lie between the second electronic component and the user surface of the electronic device.

In one embodiment, forming the first and second mirror stacks each comprises forming an even number of layers greater than 2.

In one embodiment, the process further includes forming a reflector for substantially reflecting the first and second radiation, and wherein the first and second mirror stacks lie between the first electronic component and the reflector.

In one embodiment, the process further includes forming a first intervening layer between the layers of the first pair of layers, and forming a second intervening layer between the layers of the second pair of layers.

In one embodiment, forming the first electronic component comprises forming a first organic active layer and forming the second electronic component comprises forming a second organic active layer.

In one embodiment, a composition including the electronic device described above is provided.

In one embodiment, an organic electronic device having an active layer including the electronic device described above is provided.

In one embodiment, an article useful in the manufacture of an organic electronic device, comprising the electronic device described above is provided.

In one embodiment, compositions are provided comprising the above-described compounds and at least one solvent, processing aid, charge transporting material, or charge blocking material. These compositions can be in any form, including, but not limited to solvents, emulsions, and colloidal dispersions.

### DEFINITIONS

The use of “a” or “an” are employed to describe elements and components of the invention. This is done merely for convenience and to give a general sense of the invention. This description should be read to include one or at least one and the singular also includes the plural unless it is obvious that it is meant otherwise.

The term “active” when referring to a layer or material is intended to mean a layer or material that exhibits electronic or electro-radiative properties. An active layer material may emit radiation or exhibit a change in concentration of electron-hole pairs when receiving radiation. Thus, the term “active material” refers to a material which electronically facilitates the operation of the device. Examples of active materials include, but are not limited to, materials which conduct, inject, transport, or block a charge, where the charge can be either an electron or a hole. Examples of inactive materials include, but are not limited to, planarization materials, insulating materials, and environmental barrier materials.

The term “actual thickness” is intended to mean a thickness of one or more layers within an electronic device or other physical object.

The term “adjacent,” does not necessarily mean that a layer, member or structure is immediately next to another layer, member or structure. A combination of layer(s), member(s) or structure(s) that directly contact each other are still adjacent to each other.

The term “adjacent to,” when used to refer to any combination of one or more layers, one or more members, or one or more structures in a device, does not necessarily mean that one layer, member, or structure is immediately next to another layer, member or structure. Layer(s), member(s) or structure(s) that directly contact each other are still adjacent to each other.

The terms “array,” “peripheral circuitry,” and “remote circuitry” are intended to mean different areas or components of an electronic device. For example, an array may include pixels, cells, or other structures within an orderly arrangement (usually designated by columns and rows). The pixels, cells, or other structures within the array may be controlled by peripheral circuitry, which may lie on the same substrate as the array but outside the array itself. Remote circuitry typically lies away from the peripheral circuitry and can send signals to or receive signals from the array (typically via the peripheral circuitry). The remote circuitry may also perform functions unrelated to the array. The remote circuitry may or may not reside on the substrate having the array.

The term “blue light-emitting organic layer” is intended to mean an organic layer capable of emitting radiation that has an emission maximum at a wavelength in a range of approximately 400 to 500 nm.

The term “calculated thickness” is intended to mean a thickness of one or more layers that is determined by an equation. An actual thickness and a calculated thickness may be the same or different from each other.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The term “electronic component” is intended to mean a lowest level unit of a circuit that performs an electrical or electro-radiative (e.g., electro-optic) function. An electronic component may include a transistor, a diode, a resistor, a capacitor, an inductor, a semiconductor laser, an optical switch, or the like. An electronic component does not include parasitic resistance (e.g., resistance of a wire) or parasitic capacitance (e.g., capacitive coupling between two conductors electrically connected to different electronic components where a capacitor between the conductors is unintended or incidental).

The term “electronic device” is intended to mean a collection of circuits, electronic components, or combinations thereof that collectively, when properly electrically connected and supplied with the appropriate potential(s), performs a function. An electronic device may include or be part of a system. An example of an electronic device includes a display, a sensor array, a computer system, an avionics system, an automobile, a cellular phone, other consumer or industrial electronic product, or any combination thereof.

The term “green light-emitting organic layer” is intended to mean an organic layer capable of emitting radiation that has an emission maximum at a wavelength in a range of approximately 500 to 600 nm.

The term “immediately adjacent” is intended to mean that two or more objects are near each other and that no other significant object lies between such two or more objects.

In one embodiment, the two or more objects touch each other. In another embodiment, two or more objects may be separated by an insignificant gap (e.g., a contiguous arrangement). Any of the objects can include a layer, member, structure, or any combination thereof.

The term “layer” is used interchangeably with the term “film” and refers to a coating covering a desired area. The area can be as large as an entire device or a specific functional area such as the actual visual display, or as small as a single sub-pixel. Films can be formed by any conventional deposition technique, including vapor deposition and liquid deposition. Liquid deposition techniques include, but are not limited to, continuous deposition techniques such as spin coating, gravure coating, curtain coating, dip coating, slot-die coating, spray-coating, and continuous nozzle coating; and discontinuous deposition techniques such as ink jet printing, gravure printing, and screen printing.

The term “mirror stack” is intended to mean a plurality of layers, wherein the plurality of layers acts a mirror. In one embodiment, a mirror stack can include one or more Bragg reflectors.

The term “organic active layer” is intended to mean one or more organic layers, wherein at least one of the organic layers, by itself, or when in contact with a dissimilar material is capable of forming a rectifying junction.

The term “organic electronic device” is intended to mean a device including one or more semiconductor layers or materials. Organic electronic devices include, but are not limited to: (1) devices that convert electrical energy into radiation (e.g., a light-emitting diode, light emitting diode display, diode laser, or lighting panel), (2) devices that detect signals through electronic processes (e.g., photodetectors photoconductive cells, photoresistors, photoswitches, phototransistors, phototubes, infrared (“IR”) detectors, or biosensors), (3) devices that convert radiation into electrical energy (e.g., a photovoltaic device or solar cell), and (4) devices that include one or more electronic components that include one or more organic semiconductor layers (e.g., a transistor or diode). The term device also includes coating materials for memory storage devices, antistatic films, biosensors, electrochromic devices, solid electrolyte capacitors, energy storage devices such as a rechargeable battery, and electromagnetic shielding applications.

The term “organic layer” is intended to mean one or more layers, wherein at least one of the layers comprises a material including carbon and at least one other element, such as hydrogen, oxygen, nitrogen, fluorine, etc.

The term “pair of layers” is intended to mean an even number of layers and can include 2, 4, 6, 8, or more layers.

“Photoactive” refers to a material that emits light when activated by an applied voltage (such as in a light emitting diode or chemical cell) or responds to radiant energy and generates a signal with or without an applied bias voltage (such as in a photodetector).

The term “radiation-emitting component” is intended to mean an electronic component, which when properly biased, emits radiation at a targeted wavelength or spectrum of wavelengths. The radiation may be within the visible-light spectrum or outside the visible-light spectrum (UV or IR). A light-emitting diode is an example of a radiation-emitting component.

The term “radiation-responsive component” is intended to mean an electronic component, which when properly biased, can respond to radiation at a targeted wavelength or spectrum of wavelengths. The radiation may be within the visible-light spectrum or outside the visible-light spectrum (UV or IR). An IR sensor and a photovoltaic cell are examples of radiation-sensing components.

The term “rectifying junction” is intended to mean a junction within a semiconductor layer or a junction formed by an interface between a semiconductor layer and a dissimilar material, in which charge carriers of one type flow easier in one direction through the junction compared to the opposite direction. A pn junction is an example of a rectifying junction that can be used as a diode.

The term “red light-emitting organic layer” is intended to mean an organic layer capable of emitting radiation that has an emission maximum at a wavelength in a range of approximately 600 to 700 nm.

The term “substrate” is intended to mean a workpiece that can be either rigid or flexible and may include one or more layers of one or more materials, which can include, but are not limited to, glass, polymer, metal, or ceramic materials, or combinations thereof.

The term “user surface” is intended to mean a surface of the electronic device principally used during normal operation of the electronic device. In the case of a display, the surface of the electronic device seen by a user would be a user surface. In the case of a sensor or photovoltaic cell, the user surface would be the surface that principally transmits radiation that is to be sensed or converted to electrical energy. Note that an electronic device may have more than one user surface.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### EXAMPLES

The concepts described herein will be further described in the following examples, which do not limit the scope of the invention described in the claims.

The use of an optical resonator in connection with an electronic device is discussed in commonly-assigned U.S. patent application having Attorney Docket No. DPUC-0142/UC0490 PCT NA, which was filed Dec. 21, 2005, and which is incorporated by reference herein in its entirety.

In an embodiment, one or more Bragg reflectors may be used as part of, for example, a mirror stack. A Bragg reflector has a dielectric layered structure having alternating quarter-wave layers of two different materials with different indices of refraction. The resonant wavelength corresponds to:

$${n}_{1} {d}_{1} = \frac{1}{4} λ \\ {n}_{2} {d}_{2} = \frac{1}{4} λ \qquad ( 1 )$$

wherein n₁, n₂ and d₁, d₂ are the indices of refraction and the thicknesses of the dielectric layers, respectively.

To reflect a specific wavelength, at least two quarter-wave layers of two different materials with different indices of refraction should be present. One period in a Bragg reflector has two sub-layers, (n₁, d₁) and (n₂, d₂) to satisfy the above equation. A Bragg reflector that reflects a specific wavelength could have one or more periods. The number of the periods determines the shape of the reflection spectrum and the peak reflectance. Equation (1) determines which wavelength is reflected.

To have two resonant modes (reflecting two wavelengths λ and λ′), two Bragg reflectors having two different periods are stacked. The first Bragg reflector should satisfy the following equation:

$${n}_{1} {d}_{1} = \frac{1}{4} λ$$

$${n}_{2} {d}_{2} = \frac{1}{4} λ$$

while the second Bragg reflector should satisfy the following equation:

$${n}_{3} {d}_{3} = \frac{1}{4} {λ}^{′}$$

$${n}_{4} {d}_{4} = \frac{1}{4} {λ}^{′}$$

wherein n₃, n₄ and d₃, d₄ are the indices of refraction and the thicknesses of the dielectric layers.

If three resonant modes are required in a full color display, three Bragg reflectors with three different periods should be stacked, similar to the case of two stacking Bragg reflectors discussed above. If several Bragg reflectors with different periods are stacked, or is an aperiodic layered medium in which the local period is an increasing (or decreasing) function of position is used, a broad band Bragg reflector could be constructed. Each Bragg reflector serves as a reflector for each wavelength. If the bandwidths are wide enough to have substantial overlap, the whole Bragg reflector can reflect a broad band of light.

According to an embodiment, in a finished electronic device the mirror stacks of Bragg reflectors may lie in the radiation paths for the three types of electronic components that comprise each light emitter. For example, a first type of electronic component may be a blue light emitter, a second type of electronic component may be a green light emitter and the third type of electronic component may be a red light emitter. Each of the first, second and third mirror stacks may lie within the radiation path for the blue, green and red emitters, respectively. In another embodiment, a white light emitter may be used. In an embodiment, the mirror stacks can be designed to emit radiation at 435, 535 and 635 nm, each with a bandwidth of approximately 50 nm, for example.

After reading this specification, skilled artisans will appreciate that the mirror stacks may be used with the same type of light emitter (e.g., a white light emitter) or different types of light emitters (e.g., blue, green and red emitters).

An embodiment may be used in connection with other types of emitters. For example, an electronic device having a different type of electronic components is designed for yet another different wavelength or spectrum of wavelengths, whether visible or not. An embodiment may also be employed in connection with other types of electronic components, such as, for example, a radiation sensor, a photovoltaic cell, another radiation-emitting or radiation-responsive electronic component or any combination thereof. When used with a radiation sensor, the mirror stack may help to reduce the intensities of wavelengths of radiation that are not of interest as compared to radiation at a particular wavelength or spectrum of wavelengths that is of interest.

The mirror stack may be located nearly anywhere in a radiation path. For example, the mirror stack may lie between the electronic components and a user side of the electronic device (e.g., the side of the device that emits light if the device is an emitter, the side of the device that receives light if the device is a detector, etc.).

In one embodiment, the third type of electronic component may be a blue light emitter. In another embodiment, one or more other types of electronic components can be used that are designed for one or more wavelengths outside the visible light spectrum, such as infrared, ultraviolet, etc. By stacking a plurality of periodic layered media with different periods, several wavelengths can be used as the resonant modes.

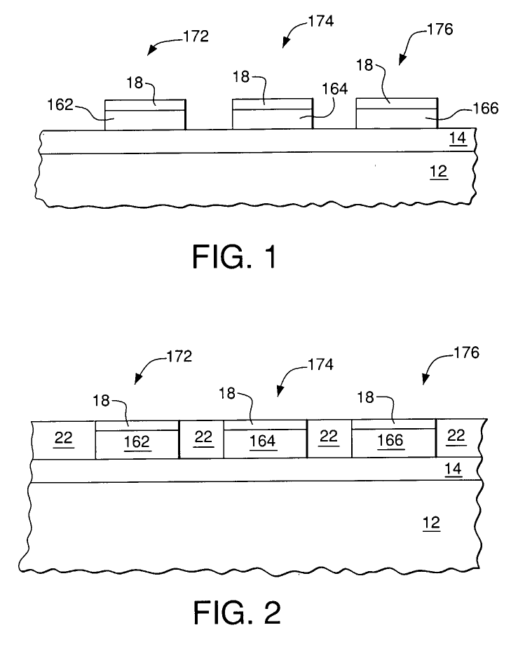

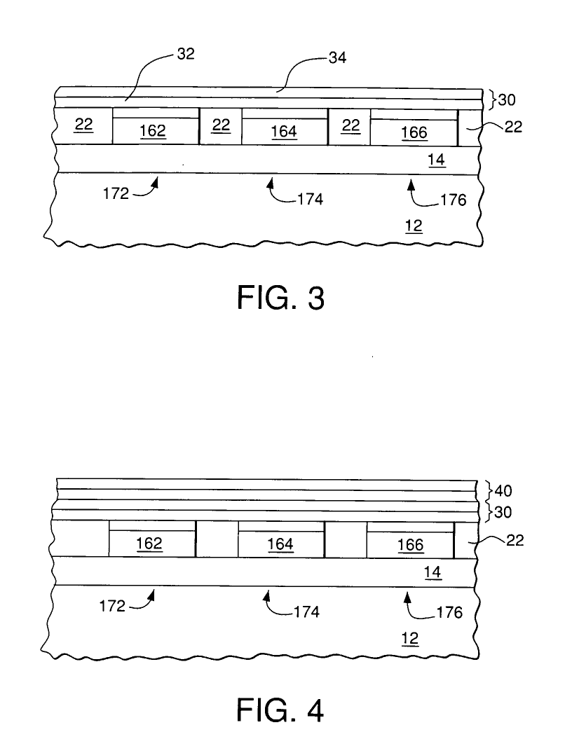

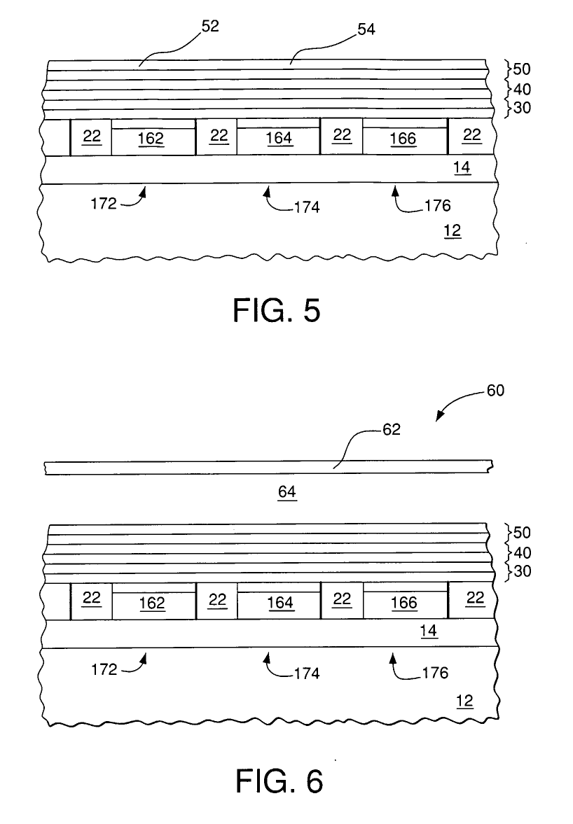

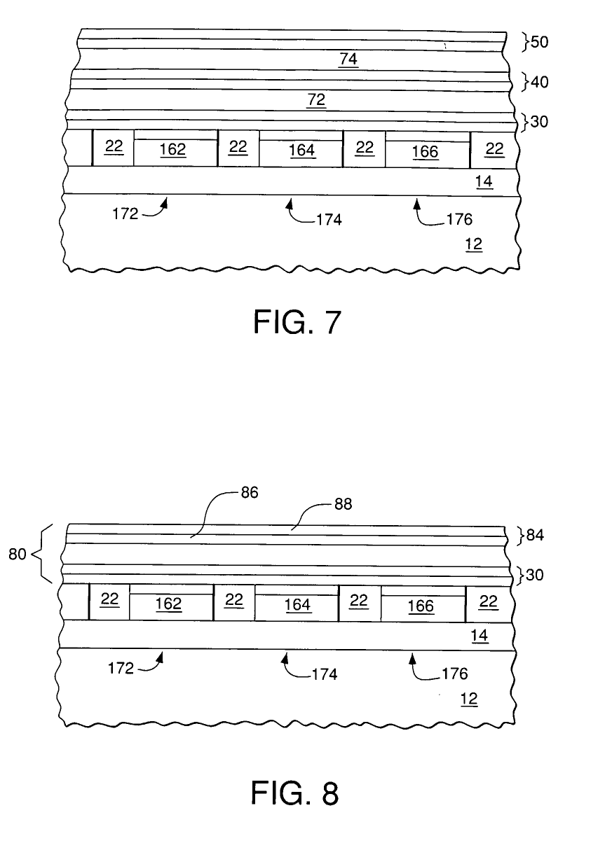

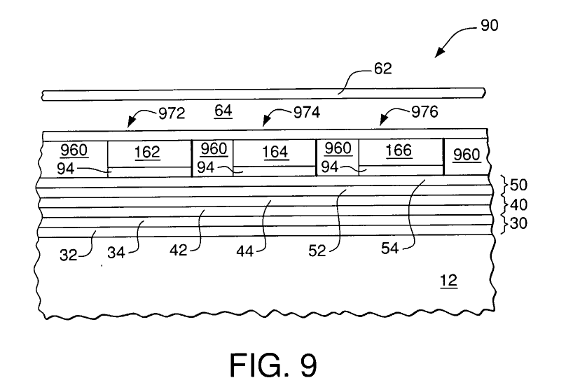

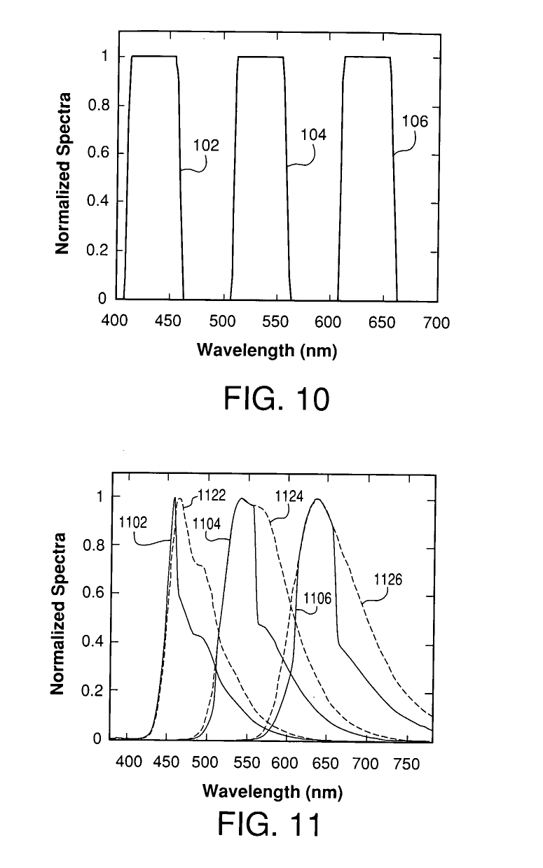

FIG. 1 includes an illustration of a cross-sectional view of a portion of substrate 12 over which electronic components 172, 174 and 176 have been fabricated during the formation of an electronic device. Substrate 12 can include one or more layers that can include an insulating material, such as glass or other ceramic material, plastic, or any combination thereof. Substrate 12 may be rigid or flexible, and may or may not allow radiation to be transmitted. In one embodiment, the user side of the electronic device is opposite substrate 12. In this embodiment, the transmission of radiation through substrate 12 is not important. In another embodiment, the user side of the electronic device lies on the side of substrate 12 opposite the side of electronic components 172, 174 and 176. In this embodiment, at least 70% of the radiation to be emitted or responded to by electronic components 172, 174 and 176 may be transmitted through substrate 12. In the embodiment illustrated in FIGS. 1 through 6, a bottom-emission electronic device (i.e., where substrate 12 is on a user side of electronic device 10) is being formed, and thus, the transmission of radiation through substrate 12 is not important.

First electrode 14 may be formed over substrate 12. In one embodiment, first electrode 14 can act as a common anode for the display. In another embodiment, first electrode 14 could be replaced by a plurality of first electrodes that may be coupled to control circuits (not illustrated) within substrate 12. First electrode 14 can include one or more layers of one or more materials that are conventionally used for anodes within OLEDs. First electrode 14 can reflect part or substantially all radiation incident on first electrode 14. In one particular embodiment, first electrode 14 can include a first layer and a second layer (not shown), wherein the first layer lies closer to substrate 12 as compared to the second layer. The first layer may reflect part or substantially all of the radiation reaching the first layer and can include silver, aluminum, other partially or highly reflective, conductive material, or any combination thereof. The second layer can include a relatively more transparent layer as compared to the first layer and may include indium tin oxide (“ITO”), indium zinc oxide (“IZO”), aluminum zinc oxide (“AZO”) or the like. First electrode 14 can include a conductive organic polymer and may be formed using a conventional deposition technique.

Organic layers 162, 164 and 166 can be formed over first electrode 14. Organic layers 162, 164 and 166 can have substantially the same or different compositions and have one or more layers. For example, organic layers 162, 164 and 166 may have the same or different organic active layers. In one embodiment, organic layer 162 may include a blue light-emitting organic layer, organic layer 164 may include a green light-emitting organic layer and organic layer 166 may include a red light-emitting organic layer. In another embodiment, each of organic layers 162, 164 and 166 may include a white light-emitting organic layer. In still another embodiment, one or more other organic layers may be used in conjunction with the organic active layer(s). Such other layer(s) can include a buffer layer, a charge-blocking layer, a charge-injection layer, a charge-transport layer or any combination thereof. In still another embodiment, any of organic layers 162, 164 and 166 may include a single layer, wherein different portions of the single layer serves different purposes (e.g., one portion acts as a hole-transport layer and another portion acts as an electroluminescent layer). In still a further embodiment, any one or more of organic layers 162, 164 and 166 may be designed to respond to radiation such as, for example, a sensor or a photovoltaic cell. The composition and thickness of organic layers 162, 164 and 166 can be conventional, for example.

In one embodiment, each layer within each of organic layers 162, 164 and 166 can include a small molecule or polymer (which may or may not include a copolymer) material. A conventional deposition can be used to form any one or more of organic layers 162, 164 and 166. The deposition can include a chemical vapor deposition, physical vapor deposition (e.g., evaporation, sputtering or the like), casting, spin coating, ink-jet printing, continuous printing, etc. Each of organic layers 162, 164 and 168 may be patterned as deposited or may be deposited and subsequently patterned. In an alternative embodiment, one or more substrate structures (not illustrated) may be formed over substrate 12 before forming organic layers 162, 164 and 166. An example of a substrate structure can include a well structure, a cathode separator or the like.

Second electrodes 18 may be formed over organic layers 162, 164 and 166. Second electrodes 18 can act as cathodes for electronic components 172, 174 and 176. In one embodiment, second electrodes 18 may include a first layer and a second layer, wherein the first layer lies closer to organic layers 162, 164 and 166 as compared to the second layer. The first layer can include a material that has a relatively low work function, for example. An example of such a material may include, for example, a Group 1 metal (e.g., Li, Cs, or the like), a Group 2 (alkaline earth) metal (e.g., Mg, Ca, or the like), an alkali metal compounds (e.g., Li₂O, LiBO₂, or the like), a rare earth metal including a lanthanide or an actinide, an alloy of any such metals, or any combination thereof. The first layer can also include alkali fluorides or alkaline earth fluorides, such as, for example, LiF, CsF, MgF₂, CaF₂, or the like. A conductive polymer with a low work function may also be used.

The second layer may include a material that helps to protect the first layer during processing of electronic device 10. The second layer can be more stable in air as compared to the first layer. The second layer can include, for example, ITO, IZO, AZO, Ag, Al or any combination thereof. Second electrodes 18 may be transparent or partially transparent to radiation that is emitted from organic layers 162, 164 and 166 or radiation to which organic layers 162, 164 and 166 are designed to respond. In one particular embodiment, the second layer partially reflects radiation.

Second electrodes 18 can be patterned as deposited or can be deposited and subsequently patterned using one or more conventional techniques. Although not illustrated, in finished electronic device, second electrodes 18 may be coupled to control circuits. Alternatively, if separate first electrodes would be used, a common second electrode may also be used. In an embodiment, second electrode 18 has a thickness of up to 1 micron.

Optional planarization layer 22 may be formed between electronic components 172, 174 and 176, as illustrated in FIG. 2. Planarization layer 22 can help reduce topology changes for subsequently-formed layers such as, for example, mirror stacks. Planarization layer 22 may include one or more layers of an organic or inorganic electrically insulating material. Planarization layer 22 may be patterned as deposited or deposited and subsequently patterned. The elevations of the top surfaces of planarization layer 22 can be approximately the same as the top surfaces of second electrodes 18. In another embodiment, the elevations may be significantly different.

In still another embodiment, a substrate structure (not illustrated) may be present between electronic components 172, 174 and 176. In an embodiment, planarization layer 22 may be formed within openings of the substrate structure such that the top surfaces of the substrate structure and planarization layer 22 are at approximately the same elevation. In another embodiment, the tops surfaces may be significantly different. In yet another embodiment, planarization layer 22, substrate structure, or both are not used.

First mirror stack 30 is formed over electronic components 172, 174 and 176, as illustrated in FIG. 3. First mirror stack 30 can include a pair of layers 32 and 34. First mirror stack 30 may be designed for a wavelength or a spectrum of wavelengths. In one embodiment, electronic components 172, 174 and 176 can be a blue light-emitting component, a green light-emitting component, and a red light-emitting component, respectively. First mirror stack 30 may be designed for blue, green or red light. In one particular embodiment, the first mirror stack 30 can be designed for blue light. In this embodiment, blue light may correspond to radiation having a spectrum of wavelengths corresponding to 400 to 500 nm. Any wavelength within 400 to 500 nm can be used, and in one particular embodiment may be 435 nm. In another embodiment, the wavelength may correspond to the emission maximum for electronic component 172.

The calculated thickness for each of layers 32 and 34 can be determined by any of Equations 1, 2 or 3. In order to calculate the thickness, a first targeted wavelength and a first refractive index can be determined. In one embodiment, the first targeted wavelength is 435 nm. The refractive index can depend on the one or more materials used for layers 32 and 34. A nearly limitless number of materials can be used for the layers within a mirror stack. The electrical characteristics for layer 32, 34, or all layers within first mirror stack 30 can vary from conductive to semiconductive to insulating.

A potential material for a layer within a mirror stack can comprise one or more inorganic materials. An example of an inorganic material includes an elemental metal (e.g., W, Ta, Cr, In, or the like), a metallic alloy (e.g., Mg—Al, Li—Al, or the like), a metallic oxide (e.g., CrₓO_{y}, FeₓO_{y}, In₂O₃, SnO, ZnO, or the like), a metallic alloy oxide (e.g., InSnO, AlZnO, AlSnO, or the like), a metallic nitride (e.g., AlN, WN, TaN, TiN, or the like), a metallic alloy nitride (e.g., TiSiN, TaSiN, or the like), a metallic oxynitride (e.g., AlON, TaON, or the like), a metallic alloy oxynitride, a Group 14 oxide (e.g., SiO₂, GeO₂, or the like), a Group 14 nitride (e.g., Si₃N₄, silicon-rich Si₃N₄, or the like), a Group 14 oxynitride (e.g., silicon oxynitride, silicon-rich silicon oxynitride, or the like), a Group 14 material (e.g., graphite, Si, Ge, SiC, SiGe, or the like), a Group 13-15 semiconductor material (e.g., GaAs, InP, GaInAs, or the like), a Group 12-16 semiconductor material (e.g., ZnS, ZnSe, CdS, ZnSSe, or the like), or any combination thereof. An elemental metal refers to a layer that consists essentially of a single element and is not a homogenous alloy with another metallic element or a molecular compound with another element. For the purposes of a metallic alloy, silicon can be considered a metal. In many embodiments, a metal, whether as an elemental metal or as part of a molecular compound (e.g., metal oxide, metal nitride, or the like) may be a transition metal (an element within Groups 3 to 12 in the Periodic Table of the Elements) including chromium, tantalum, gold, or the like.

A potential material for a layer within a mirror stack can comprise one or more organic materials. An organic material can include a polyolefin (e.g., polyethylene, polypropylene, or the like), a polyester (e.g., polyethylene terephthalate, polyethylene naphthalate or the like), a polyimide, a polyamide, a polyacrylonitrile, a polymethacrylonitrile, a perfluorinated or partially fluorinated polymer (e.g., polytetrafluoroethylene, a copolymer of tetrafluoroethylene and a polystyrene, or the like), a polycarbonate, a polyvinyl chloride, a polyurethane, a polyacrylic resin, including a homopolymer or a copolymer of an ester of an acrylic or methacrylic acid, an epoxy resins, a Novolac resin, an organic charge transfer compounds (e.g., tetrathiafulvalene tetracyanoquinodimethane (“TTF-TCNQ”) and the like), or any combination thereof.

In still another embodiment, a layer within a mirror stack can include a combination of one or more inorganic materials and one or more organic materials.

The refractive index for the material(s) may be determined using a technical handbook. Alternatively, the refractive index for the material(s) may be determined by using a conventional optical measuring tool (e.g., an ellipsometer). Some exemplary refractive indices include 1.5 for SiO₂, 2.0 for Si₃N₄, and 1.6 for many polymer materials.

In one embodiment, the targeted wavelength can be 635 nm, and layer 32 may include SiO₂ (η of 1.5). Using any of the prior equations, a calculated thickness for layer 32 may be approximately 73 nm. To allow for some process margin, the actual thickness can be +/−10% of the calculated thickness, for example. In one particular embodiment, the actual thickness of the layer 32 can be in a range of 66 to 80 nm. If the refractive index of the layer 32 would be 1.6, then the calculated thickness would be approximately 68 nm, and a range for the actual thickness can be 61 to 75 nm.

Layer 34 can include any of the previously described materials for a layer within a mirror stack. Layer 34 may have a different composition as compared to layer 32. In another embodiment, layers 32 and 34 can include substantially the same material if an interface can be formed between the layers. In an embodiment, layer 34 may include Si₃N₄ (η of 2.0), and thus, the calculated thickness is approximately 54 nm, and a range of actual thicknesses (e.g., +/−10%) can be 49 to 59 nm.

Each of the layers within first mirror stack 30 can be formed using a conventional deposition technique, such as chemical vapor deposition, physical vapor deposition (e.g., evaporation, sputtering, or the like), casting, spin coating, ink-jet printing, continuous printing, or the like.

In another embodiment (not illustrated), the first mirror stack 30 can include one or more additional layers. In one embodiment, first mirror stack 30 can include one or more pairs of layers. After reading this specification, skilled artisans will be able to determine the compositions and thicknesses of layers within a mirror stack to achieve their needs or desires.

Second mirror stack 40 may be formed over electronic components 172, 174 and 176, as illustrated in FIG. 4. Second mirror stack 40 can include a pair of layers 42 and 44. Second mirror stack 40 may be designed for a wavelength or a spectrum of wavelengths different from first mirror stack 30. Second mirror stack 40 may be designed for blue, green or red light. In one particular embodiment, second mirror stack 40 can be designed for green light. In this embodiment, green light may correspond to radiation having a spectrum of wavelengths corresponding to 500 to 600 nm. Any wavelength within 500 to 600 nm can be used, and in one particular embodiment is 535 nm. In another embodiment, the wavelength may correspond to the emission maximum for electronic component 174.

The calculated thickness for each of layers 42 and 44 can be determined by any of Equations 1, 2 or 3. In order to calculate the thickness, a second targeted wavelength and a second refractive index can be determined. In one embodiment, the second targeted wavelength is 535 nm. The refractive index can depend on the one or more materials used for layers 42 and 44. The electrical characteristics for layer 42, 44, or all layers within second mirror stack 40 can vary from conductive to semiconductive to insulating.

Any one or more of the materials previously described with respect to layers 32 and 34 within first mirror stack 30 can be used for the layers, including layers 42 and 44, within second mirror stack 40.

In one embodiment, the targeted wavelength can be 535 nm, and layer 42 may include SiO₂ (η of 1.5). Using any of the prior equations, the calculated thickness for layer 42 can be approximately 89 nm. To allow for some process margin, the actual thickness can be +/−10% of the calculated thickness, for example. In one embodiment, therefore, the actual thickness of layer 42 can be in a range of 80 to 98 nm. If the refractive index of layer 42 would be 1.6, then the first calculated thickness would be approximately 84 nm, and a range for the actual thickness can be 76 to 92 nm.

Layer 44 can include any of the previously described materials for a layer within a mirror stack. Layer 44 may have a different composition as compared to layer 42. In another embodiment, layers 42 and 44 can include substantially the same material if an interface can be formed between the layers. In an embodiment, layer 44 may include Si₃N₄ (η of 2.0), and thus, the calculated thickness is approximately 67 nm, and a range of actual thicknesses can be 60 to 74 nm.

Each of the layers within second mirror stack 40 can be formed using a conventional deposition technique, such as chemical vapor deposition, physical vapor deposition (e.g., evaporation, sputtering or the like), casting, spin coating, ink-jet printing, continuous printing or the like.

In another embodiment (not illustrated), second mirror stack 40 can include one or more additional layers. In one embodiment, second mirror stack 40 can include one or more pairs of layers.

A third mirror stack 50 may be formed over the electronic components 172, 174 and 176, as illustrated in FIG. 5. Third mirror stack 50 can include a pair of layers 52 and 54. Third mirror stack 50 may be designed for a wavelength or a spectrum of wavelengths different from first mirror stack 30 and second mirror stack 40. Third mirror stack 50 may be designed for blue, green or red light. In one particular embodiment, third mirror stack 50 can be designed for red light. In this embodiment, red light may correspond to radiation having a spectrum of wavelengths corresponding to 600 to 700 nm. Any wavelength within 600 to 700 nm can be used, and in one particular embodiment is 635 nm. In another embodiment, the wavelength may correspond to the emission maximum for electronic component 176.

The calculated thickness for each of layers 52 and 54 can be determined by any of Equations 1, 2 or 3. In order to calculate the thickness, a third targeted wavelength is 635 nm. The refractive index can depend on the one or more materials used for layers 52 and 54. The electrical characteristics for layer 52, 54, or all layers within third mirror stack 50 can vary from conductive to semiconductive to insulating.

Any one or more of the materials previously described with respect to layers 32 and 34 within the first mirror stack 30 can be used for the layers, including layers 52 and 54, within the third mirror stack 50.

In one embodiment, the targeted wavelength can be 635 nm, and layer 52 can include SiO₂ (η of 1.5). Using any of the prior equations, the calculated thickness for layer 52 can be approximately 106 nm. To allow for some process margin, the actual thickness can be +/−10% of the calculated thickness, for example. In one particular embodiment, the actual thickness of layer 52 can be in a range of 95 to 117 nm, for example. If the refractive index of layer 52 would be 1.6, then the calculated thickness would be approximately 99 nm, and a range for the actual thickness can be 89 to 109 nm.

Layer 54 can include any of the previously described materials for a layer within a mirror stack. Layer 54 may have a different composition as compared to layer 52. In another embodiment, layers 52 and 54 can include substantially the same material if an interface can be formed between the layers. In an embodiment, layer 54 may include Si₃N₄ (η of 2.0), and thus, the calculated thickness is approximately 79 nm, and a range of actual thicknesses can be 71 to 87 nm.

Each of the layers within third mirror stack 50 can be formed using a conventional deposition technique, such as chemical vapor deposition, physical vapor deposition (e.g., evaporation, sputtering or the like), casting, spin coating, ink-jet printing, continuous printing or the like.

In another embodiment (not illustrated), third mirror stack 50 can include one or more additional layers. In one embodiment, third mirror stack 50 can include one or more pairs of layers.

Other circuitry not illustrated in FIGS. 1 through 5 may be formed using any number of the previously described or additional layers. Although not shown, additional insulating layer(s) and interconnect level(s) may be formed to allow for circuitry in peripheral areas (not shown) that may lie outside the array. Such circuitry may include row or column decoders, strobes (e.g., row array strobe, column array strobe, or the like), sense amplifiers or the like.

Lid 62 with an optional desiccant (not illustrated) can be attached to substrate 12 at locations (not illustrated) outside the array to form electronic device 60 that is substantially completed, as illustrated in FIG. 6. Gap 64 may or may not lie between layer 54 and lid 62. In one embodiment, radiation is transmitted through lid 62. If radiation within the visible light spectrum is emitted from or to be received by electronic device 60, at least 70% of the radiation incident on lid 62 is be transmitted through lid 62. In one embodiment, lid 62 can include glass. If radiation does not need to emitted or received by electronic components 172, 174 and 176 via lid 62, lid 62 may or may not be capable of transmitting the radiation. In such an embodiment, lid 62 may include any one or more of a wide variety of materials, including glass, metal or the like. One or more materials used for lid 62 and the attaching process may be conventional.

If a desiccant is used, the location of the desiccant can depend on whether the desiccant can allow sufficient radiation that is to be emitted from or received by electronic device 60. If radiation within the visible light spectrum is emitted from or to be received by electronic device 60, at least 70% of the radiation incident on the desiccant may be transmitted through the desiccant. If the desiccant does not allow sufficient radiation to be transmitted, it may lie at one or more locations where it would not substantially interfere with the transmission of radiation. Such locations can include outside the array, or from a top view of electronic device 60, at locations between electronic components 172, 174 and 176. If radiation does not need to be emitted or received by electronic components 172, 174 and 176 via the desiccant, the desiccant can be located at nearly any position along lid 62. Gap 64 may be between the desiccant and the upper most surface of third mirror stack 50. One or more materials within the desiccant and its attachment to lid 62 are conventional.

In an alternative embodiment (not illustrated), an encapsulating layer can be formed over third mirror stack 50 in place of or before attaching lid 62. Similar to lid 62, selection of materials within the encapsulating layer may or may not depend on whether radiation is to be transmitted through the encapsulating layer. After reading this specification, skilled artisans will be able to determine the composition and thickness of the encapsulating layer depending on whether radiation is or does not have to be transmitted through the encapsulating layer. One or more materials for the encapsulating layer and deposition of the encapsulating layer may be used.

In finished electronic device 60, each of mirror stacks 30, 40 and 50 can lie within the radiation paths for each of electronic components 172, 174 and 176. Although mirror stack 30, 40 or 50 may be designed for a particular wavelength or spectrum of wavelengths that is associated with one type of electronic components (e.g., electronic component 172 may include a red light-emitting organic layer and mirror stack 30 may be designed for red light), mirror stacks 30, 40 and 50 may lie within the radiation paths for other types of electronic components that are to be photoactive to radiation at other particular wavelengths or spectra of wavelengths (e.g., mirror stack 30 may be designed for blue light and still lie within electronic components 174 and 176, which may include green and red light-emitting organic layers, respectively).

In an embodiment, electronic device 60 may include an active matrix or passive matrix display. Other electronic components (not illustrated) can be formed within or over substrate 12 or within or over another substrate, wherein such other electronic components provide or control signals provided to the electronic components, including electronic components 172, 174 and 176, within an array. Such other electronic components and their fabrication, attachment to substrate 12, or both, should be known to one of skill in the art.

Electronic device 60 may include radiation-responsive components in addition to or in place of radiation-emitting components. In one embodiment, the radiation-responsive components can be radiation sensors within a sensor array. The radiation sensors may be designed to respond to radiation at a particular wavelength or spectrum of wavelengths. In one particular embodiment, an array can include radiation-emitting components and sensors. In still another embodiment, the radiation-responsive components are photovoltaic cells or other electronic components capable of converting radiation to energy.

During operation of a display, appropriate potentials are placed on first electrode 14 and any one or more of second electrodes 18 to cause radiation to be emitted from one or more of organic layers 162, 164 or 166. More specifically, when light is to be emitted, a potential difference between the first and second electrodes allow electron-hole pairs to combine within the corresponding organic layer, so that light or other radiation may be emitted from the electronic device. In a display, rows and columns can be given signals to activate the appropriate pixels (electronic devices) to render a display to a viewer in a human-understandable form.

During operation of a radiation detector, such as a photodetector, sense amplifiers may be coupled to the first and second electrodes of the array to detect significant current flow when radiation is received by the electronic device. In a voltaic cell, such as a photovoltaic cell, light or other radiation can be converted to energy that can flow without an external energy source. After reading this specification, skilled artisans are capable of designing the electronic devices, peripheral circuitry, and potentially remote circuitry to best suit their particular needs or desires.

One or more intermediate layers may be formed between any one or more of mirror stacks 30, 40 or 50. First intermediate layer 72 can be formed over first mirror stack 30, and second intermediately layer 74 can be formed over second mirror stack 40, as illustrated in FIG. 7. In one embodiment, only one of intermediate layers 72 or 74 may be used, or in another embodiment, more intermediate layers can be used. In an embodiment, each of the one or more intermediate layers lies within the radiation path for electronic components 172, 174 and 176. Thus, each of the one or more intermediate layers can transmit at least 70% of the radiation incident or such layer, wherein such radiation is to be emitted from or received by electronic components 172, 174 and 176.

In one embodiment, one or more materials within first intermediate layer 72, second intermediate layer 74, or both can vary from conductive to semiconductive to insulating. Other considerations unrelated to radiation transmission (e.g., location with respect to another electronic component or a feature, such as a contact, an interconnect, or the like that are not illustrated) may affect the selection of material(s). After reading this specification, skilled artisans will be capable of determining the material(s) to be used within the intermediate layer(s). The one or more intermediate layer(s) can be formed using a conventional deposition technique.

In another embodiment, one or more intermediate layers may lie within a mirror stack. For example, mirror stack 80 can include first mirror stack 30 and another mirror stack 84, as illustrated in FIG. 8. Mirror stack 80, first mirror stack 30 and mirror stack 84 may be designed for radiation at a particular wavelength (e.g., 635 nm) or a spectrum of wavelengths (e.g., red light). Intermediate layer 82 can be formed after first mirror stack 30 and before mirror stack 84, which includes layers 86 and 88. In one particular embodiment, intermediate layer 82 lies between layers 34 and 86 within mirror stack 80.

The materials and formation of intermediate layer 82 can be formed using any one or more embodiments as described with respect to intermediate layers 72 and 74, as described with respect to FIG. 7.

Any one or more of the materials previously described with respect to layers 32 and 34 within first mirror stack 30 can be used for the layers, including layers 86 and 88, within mirror stack 84. The calculated thickness for each of layers 86 and 88 can be determined substantially similar to layers 32 and 34. Each of the layers within mirror stack 84 may be formed using a conventional deposition technique such as, for example, chemical vapor deposition, physical vapor deposition (e.g., evaporation, sputtering or the like), casting, spin coating, ink-jet printing, continuous printing or the like.

In an embodiment, the mirror stacks may be formed between substrate 12 and the electronic components. Mirror stacks 30, 40 and 50 may be formed over substrate 12, as illustrated in FIG. 9. Mirror stacks 30, 40 and 50 can be formed using any one or more embodiments as previously described. First electrodes 94 may be formed over third mirror stack 50. In one embodiment, first electrodes 94 act as anodes for electronic components 972, 974 and 976. The composition and formation of first electrodes 94 are substantially the same as described with respect to first electrode 14 except that first electrodes 94 are patterned in one embodiment.

In one embodiment, substrate structures 960 are formed over substrate 12 at locations between first electrodes 94. In one embodiment, substrate structures 960 are well structures, and in another embodiment, are cathode separators. The actual shapes of substrate structure 960 may differ from what is illustrated in FIG. 9. Substrate structures 960 can be formed using one or more materials, deposition technique, patterning technique, or any combination thereof as used for a well structure, a cathode separator, or a combination thereof. Organic layers 162, 164 and 166 can be formed as previously described.

Second electrode 98 may be formed over organic layers 162, 164 and 166. In one embodiment, second electrode 98 acts as a common cathode for electronic components 972, 974 and 976. The composition and formation of the second electrodes 98 is substantially the same as described with respect to second electrodes 18 except that second electrode 98 is not patterned within the array in one embodiment. Electronic device 90 can also include lid 62, a desiccant, an encapsulating layer, or any combination thereof, as previously described in other embodiments.

In electronic device 90 illustrated in FIG. 9, radiation to be emitted from or responded to by electronic components 972, 974 and 976 is transmitted through lid 62. thus, a selection of materials for lid 62 may be similar to the considerations as described with respect to the intermediate layers as described with respect to FIG. 7.

In an alternate embodiment (not illustrated), if layer 32 in FIG. 3 or layer 54 in FIG. 9 is conductive or semiconductive, an insulating layer (not illustrated) can be formed between such layer and its corresponding closest electrode (e.g., between second electrodes 18 and layer 32 or between layer 54 and first electrode 94).

In another embodiment, the first and second electrodes can be reversed. For example, the second electrode(s), which act as cathodes, may be formed closer to substrate 12 as compared to the first electrode(s), which act as anodes.

In a further embodiment, a microcavity can be used in conjunction with or include part or all of mirror stacks 30, 40 and 50.

The concepts described herein can be applied inorganic electronic components that are to be photoactive to radiation at a particular wavelength or spectrum of wavelength. An example of such an inorganic electronic component can include a silicon-based light-emitting diode.

The following examples demonstrate that an OLED device's performance may be significantly improved by application of a mirror stack according to various embodiments of the present invention. The following specific examples are meant to illustrate and not limit the scope of the invention.

### Example 1

This example demonstrates that mirror stacks including Bragg reflectors can be fabricated on the cathode side of an OLED device. The mirror stacks improve not only the color coordinates of the primary emitters, but also the contrast ratio of the electronic device. A nominal four-inch full-color active matrix display panel can be used. References are made to FIG. 6 as appropriate. Substrate 12 is glass, and first electrode 14 is ITO. On top of first electrode 14, a transparent polyaniline (“PANI”) or poly(3,4-ethylenedioxythiophene) (“PEDOT”) layer is spin-coated as a buffer layer with thickness varied in a broad range from approximately 30 nm to 500 nm (not shown in FIG. 3). Blue, green and red emitter solutions are ink-jetted onto the buffer layer at respective positions. The combinations of the buffer layer and emitters are illustrated as organic layers 162, 164 and 166 in FIG. 6. Second electrodes (Ba and Al) 18 are evaporated under vacuum and have partial reflectance. Mirror stacks 30, 40 and 50, including Bragg reflectors, are fabricated on top of second electrodes 18 by sputtering alternating dielectric layers. The thickness and the index of refraction of each layer, and the number of the layers are chosen to produce mirror stacks 30, 40 and 50 having resonant modes 102, 104 and 106, respectively, as illustrated in FIG. 10.

The emission spectra of the primary color emitters without the mirror stacks are illustrated as dashed lines 1122, 1124 and 1126 in FIG. 11 for the blue, green and red emitters, respectively. The CIE color coordinates of the red, green and blue emitters are (0.157, 0.249), (0.423, 0.559) and (0.667, 0.331), respectively. After mirror stacks 30, 40 and 50, including Bragg reflectors, are incorporated into electronic device 60, the CIE color coordinates of red, green and blue emitters are improved to (0.156, 0.200), (0.371, 0.608) and (0.680, 0.318), respectively. The emission spectra of the primary color emitters with mirror stacks 30, 40 and 50 on the cathode side are illustrated as solid lines 1102, 1104 and 1106, respectively, in FIG. 11. The contrast ratio of the nominal four-inch panel without a circular polarizer or the mirror stacks has a contrast ratio of approximately 15:1. With mirror stacks 30, 40 and 50, the contrast ratio is approximately 40:1 without a circular polarizer. The improvement factor is more than 2, and close to 3. To further improve the contrast ratio, a thin layer of an anti-reflection film can be coated on the surface of the substrate 12 to achieve a contrast ratio of more than approximately 100:1.

### Example 2

This example demonstrates that mirror stacks, including a Bragg reflector, can be fabricated on the anode side of an OLED device. The mirror stacks improve not only the color coordinates of the primary emitters, but also the contrast ratio of the electronic device. A nominal four-inch full color active matrix display panel can be used. References are made to FIG. 9 as appropriate. Substrate 12 is glass. Before forming first electrodes 94, mirror stacks 30, 40 and 50 are fabricated on top of substrate 12 by sputtering alternating dielectric layers. The thickness and the index of refraction of each layer, and the number of the layers are chosen to produce mirror stacks 30, 40 and 50 having resonant modes 102, 104 and 106, respectively, as illustrated in FIG. 10. Then, ITO layer is sputtered and patterned, serving as first electrodes 94. On top of first electrodes 94, a transparent polyaniline (“PANI”) or poly(3,4-ethylenedioxythiophene) (“PEDOT”) layer is spin-coated as a buffer layer with thickness varied in a broad range from approximately 30 nm to 500 nm. Then, the red, green and blue emitter solutions are ink-jetted onto the buffer layer at respective positions. The combinations of the buffer layer and emitters are illustrated as organic layers 162, 164 and 166. Second electrode (Ba and Al) 98 is evaporated under vacuum and has partial reflectance.

The performance of the above electronic device 90 (in FIG. 9) is substantially the same as the electronic device 60 as described in Example 1. The CIE color coordinates of red, green and blue emitters are improved from (0.157, 0.249), (0.423, 0.559) and (0.667, 0.331) to (0.156, 0.200), (0.371, 0.608), and (0.680, 0.318), respectively. The contrast ratio improvement factor is more than 2, and close to 3. When an anti-reflection film is applied on the second electrode 98, a contrast ratio of more than 100:1 is achieved.

Note that not all of the activities described above in the general description or the examples are required, that a portion of a specific activity may not be required and that one or more further activities may be performed in addition to those described. Still further, the order in which activities are listed are not necessarily the order in which they are performed. After reading this specification, skilled artisans will be capable of determining what activities can be used for their specific needs or desires.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Many aspects and embodiments have been described above and are merely exemplary and not limiting. After reading this specification, skilled artisans appreciate that other aspects and embodiments are possible without departing from the scope of the invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

1. An electronic device comprising:
a first electronic component designed to be photoactive to a first radiation having a first wavelength;
a second electronic component designed to be photoactive to a second radiation having a second wavelength; and
a first and second mirror stack adjacent to the first and second electronic components, wherein the first mirror stack includes a first pair of layers designed to reflect the first radiation and the second mirror stack includes a second pair of layers designed to reflect the second radiation.

2. The electronic device of claim 1, further comprising:
a third electronic component designed to be photoactive to a third radiation having a third wavelength; and
a third mirror stack adjacent to the first, second and third electronic components, wherein the third mirror stack includes a third pair of layers designed to reflect the third radiation.

3. The electronic device of claim 2, wherein:
each layer within the first pair of layers has a first actual thickness that is within 10% of a first calculated thickness, wherein the first calculated thickness is determined by:
n₁t₁=¼λ₁
wherein:
n₁ is a first refractive index of a particular layer within the first pair of layers;
t₁ is the first calculated thickness; and
λ₁ is the first wavelength and
each layer within the second pair of layer has a second actual thickness that is within 10% of a second calculated thickness, wherein the second calculated thickness is determined by:
n₂t₂=¼λ₂
wherein:
n₂ is a second refractive index of a particular layer within the second pair of layers;
t₂ is the second calculated thickness; and
λ₂ is the second wavelength.

4. The electronic device of claim 3, wherein:
each layer within the third pair of layers has a third actual thickness that is within 10% of a third calculated thickness, wherein the third calculated thickness is determined by:
n₃t₃=¼λ₃
wherein:
n₃ is a third refractive index of a particular layer within the third pair of layers;
t₃ is the third calculated thickness; and
λ₃ is the third wavelength.

5. The electronic device of claim 3, wherein:
the first electronic component comprises a first organic light-emitting layer configured to emit blue light;
the second electronic component comprises a second organic light-emitting layer configured to emit green light; and
the third electronic component comprises a third organic light-emitting layer configured to emit red light.

6. The electronic device of claim 1, wherein the first mirror stack further comprises a first intervening layer, and the second mirror stack further comprises a second intervening layer.

7. The electronic device of claim 1, further comprising:
a first organic active layer within the first electronic component; and
a second organic active layer within the second electronic component.

8. A process for forming an electronic device comprising:
forming a first electronic component designed to be photoactive to a first radiation having a first wavelength;
forming a second electronic component designed to be photoactive to a second radiation having a second wavelength;
forming a first mirror stack, wherein the first mirror stack includes a first pair of layers designed to reflect the first radiation; and
forming a second mirror stack, wherein the second mirror stack includes a second pair of layers designed to reflect the second radiation.

9. The process of claim 8, wherein each layer within the first pair of layers is formed to have a first actual thickness that is within 10% of a first calculated thickness, wherein the first calculated thickness is determined by:
n₁t₁=¼λ₁
wherein:
n₁ is a first refractive index of a particular layer within the first pair of layers;
t₁ is the first calculated thickness;
λ₁ is the first wavelength; and
each layer within the second pair of layer is formed to have a second actual thickness that is within 10% of a second calculated thickness, wherein the second calculated thickness is determined by:
n₂t₂=¼λ₂
wherein:
n₂ is a second refractive index of a particular layer within the second pair of layers;
t₂ is the second calculated thickness; and
λ₂ is the second wavelength.

10. The process of claim 8, further comprising:
forming a third electronic component designed to be photoactive to a third radiation having a third wavelength; and
forming a third mirror stack, wherein the third mirror stack includes a third pair of layers designed to reflect the third radiation.

11. The process of claim 10, wherein each layer within the third pair of layers is formed to have a third actual thickness that is within 10% of a third calculated thickness, wherein the third calculated thickness is determined by:
n₃t₃=¼λ₃
wherein:
n₃ is a third refractive index of a particular layer within the third pair of layers;
t₃ is the third calculated thickness; and
λ₃ is the third wavelength.

12. The process of claim 10, wherein:
the first electronic component comprises a first organic light-emitting layer configured to emit blue light;
the second electronic component comprises a second organic light-emitting layer configured to emit green light; and
the third electronic component comprises a third organic light-emitting layer configured to emit red light.

13. The process of claim 8, wherein:
the first and second mirror stacks lie between the first electronic component and a user surface of the electronic device; and
the first and second mirror stacks lie between the second electronic component and the user surface of the electronic device.

14. The process of claim 8, wherein forming the first and second mirror stacks each comprises forming an even number of layers greater than 2.

15. The process of claim 8, further comprising forming a reflector for substantially reflecting the first and second radiation, and wherein the first and second mirror stacks lie between the first electronic component and the reflector.

16. The process of claim 8, further comprising forming a first intervening layer between the layers of the first pair of layers, and forming a second intervening layer between the layers of the second pair of layers.

17. The process of claim 8, wherein:
forming the first electronic component comprises forming a first organic active layer; and
forming the second electronic component comprises forming a second organic active layer.

18. A composition including the electronic device of claim 1.

19. An organic electronic device having an active layer including the electronic device of claim 1.

20. An article useful in the manufacture of an organic electronic device, comprising the electronic device of claim 1.
